(19) United States
(12) Patent Application Publication
(10) Pub. No.: US 2003/0111013 A1
(43) Pub. Date: Jun. 19, 2003

(54) Method for the deposition of silicon germanium layers

(76) Inventors: Theodorus Gerardus Maria Oosterlaken, Oudewater (NL); Peter Marc Zagwijn, Nijkerk (NL)

Correspondence Address: KNOBBE MARTENS OLSON & BEAR LLP, 2040 MAIN STREET, FOURTEENTH FLOOR, IRVINE, CA, 92614, US

(21) Appl. No.: 10/313,089

(22) Filed: Dec. 5, 2002

Related U.S. Application Data
(60) Provisional application No. 60/343,387, filed on Dec. 19, 2001.

(51) Int. Cl. C23C 16/00

(52) U.S. Cl. 118/724; 118/715

(57) ABSTRACT

A vertical chemical vapor deposition (CVD) apparatus and methods for the deposition of compound films, such as silicon germanium films, are provided. In a preferred embodiment, the apparatus comprises a process chamber, wherein the process chamber is elongated in a first generally vertical direction; a boat to support a plurality of wafers, wherein individual wafers comprising the plurality of wafers are oriented substantially horizontally, stacked substantially vertically and spaced apart vertically; and a gas injector inside the process chamber, wherein the gas injector extends in a second generally vertical direction over about the height of the boat and comprises a plurality of gas injection holes, wherein the plurality of gas injection holes extends over about the height of the gas injector, and wherein the gas injector has a feed end connected to a source of a silicon-containing gas and a source of a germanium-containing gas. The aggregate cross-section of the holes is relatively large to prevent reactions inside the gas injector and the horizontal cross-section of gas conduction channels inside the gas injector is relatively large to facilitate distribution of the precursor source gases over the height of the boat.

### REFERENCE TO RELATED APPLICATION

This application claims the priority benefit of U.S. Provisional Application Serial No. 60/343,387, filed Dec. 19, 2001.

### FIELD OF THE INVENTION

The present invention relates to the field of integrated circuit fabrication and, more particularly, to a method and apparatus for the chemical vapor deposition (CVD) of compound films onto semiconductor substrates.

### BACKGROUND OF THE INVENTION

Due in part to low pressure CVD techniques, chemical vapor deposition has been widely applied in the semiconductor industry. Early CVD reactors included elongated batch furnaces. Today, these batch furnaces are still used for many applications.

Such batch furnaces use an elongated process chamber that is generally in the shape of a tube and is surrounded by heating elements. Typically, semiconductor wafers are loaded into the furnace with the wafer faces oriented perpendicular to the elongate axis of the tube. Inside the furnace, the wafers are spaced apart, with limited spacing between the wafers to allow for gas diffusion between and contact with the wafers.

Typically, process gases are supplied to the interior of the furnace from one end of the furnace. The gases generally flow in a direction parallel to the elongate axis and are exhausted from a furnace end opposite to the end from which they entered. Process gases enter the space between adjacent wafers by diffusion. In this way, a large number of wafers can be processed simultaneously, making processing using these batch furnaces an efficient and economical production method.

While batch processing has continued to be used due in part to economic considerations, the usefulness of such processing has been challenged by the more stringent requirements of modem integrated circuit fabrication. In particular, as the dimensions of microelectronic devices become smaller, the physical characteristics of the deposited films or layers, including compositional and thickness uniformity, become more important. As a result, refinement of batch processing apparatus and methods to meet these more stringent requirements is an on-going process.

Thus, it is an object of the present invention to provide an apparatus and a method for the batch deposition of uniform compound films, such as silicon germanium films.

### SUMMARY OF THE INVENTION

One aspect of the present invention provides a chemical vapor deposition furnace comprising a process chamber that is elongated in a first generally vertical direction; a boat to support a plurality of wafers, wherein individual wafers comprising the plurality of wafers are oriented substantially horizontally, stacked substantially vertically and spaced apart vertically; and a gas injector inside the process chamber. The gas injector extends in a second generally vertical direction over about the height of the boat and comprises a plurality of gas injection holes. The gas injector has a feed end connected to a source of a silicon-containing gas and a source of a germanium-containing gas.

In one preferred embodiment, the gas injector is configured such that a horizontal cross-sectional area of a channel inside the gas injector for conducting gas is at least about 100 mm² and the gas injection holes have an aggregate cross-sectional area of at least about 30 mm². With such a gas injector, gas phase reactions inside that injector may be minimized.

In another preferred embodiment, the gas injector has a horizontal cross-section with an oblong shape, the gas injector being oriented such that a side of the oblong shape having the longer dimension faces toward the center of the chemical vapor deposition furnace.

In accordance with another aspect of the invention, a gas injector is provided for releasing gases into a chemical vapor deposition chamber. The gas injector comprises a vertically extending, elongated and hollow structure having a plurality of holes along a length of the structure The structure is located inside the chamber, which extends in a vertical direction. In addition, the gas injector has a feed end at a bottom of the structure. The feed end is connected to a source of a first precursor gas and a source of a second precursor gas. The distance between the holes comprising the plurality of holes decreases with increasing distance from the feed end.

In accordance with yet another aspect of the invention, a chemical vapor deposition furnace is provided for depositing compound films on a plurality of wafers. The furnace comprises a process chamber elongated in a first direction along a first axis and a boat to support the plurality of wafers. Individual wafers of the plurality of wafers on the boat are oriented substantially perpendicular to the first axis, stacked and spaced apart substantially along the first axis. The furnace also includes a gas injector inside the reaction chamber, the gas injector generally extending along the first axis and comprising a plurality of gas injection holes and having a feed end connected to a source of a first precursor gas and a source of a second precursor gas. The plurality of gas injection holes extends over about a gas injector length. The process chamber can extend in various directions, e.g., horizontally or vertically.

In accordance with another aspect of the invention, a method is provided for manufacturing semiconductor devices, the method comprising distributing a reactant gas up a vertical axis of a chemical vapor deposition chamber and horizontally flowing the reactant gas from a plurality of locations along the axis into a reaction space in the chamber. Distributing the reactant gas up the vertical axis of the chemical vapor deposition chamber is performed inside the chamber, but not in the reaction space.

### BRIEF DESCRIPTION OF THE FIGURES

FIG. 1a is a schematic cross-sectional top view of a tube-shaped process chamber in accordance with preferred embodiments of the present invention;

FIG. 1b is a schematic cross-sectional side view of the tube-shaped process chamber of FIG. 1a, illustrating generalized dimensions of the process chamber;

FIG. 2 is a schematic cross-sectional side view of an elongated furnace with a gas injector, constructed in accordance with preferred embodiments of the present invention;

FIG. 3 is a perspective view of the process chamber of FIG. 2, as viewed from the bottom of the process chamber;

FIG. 4 is a schematic front view of a gas injector in accordance with one illustrative embodiment of the present invention;

FIG. 5 is a perspective view of the gas injector of FIG. 4;

FIG. 6 is a horizontal cross-sectional view of the gas injector of FIG. 4;

FIG. 7 is an exploded side view of a tubular process chamber with a liner and a gas injector in accordance with preferred embodiments of the present invention;

FIG. 8 is a thickness-position and Ge-concentration-position plot showing the results of a chemical vapor deposition of a silicon germanium layer performed in accordance with a prior art batch process; and

FIG. 9 shows the results of a chemical vapor deposition of a silicon germanium layer performed in accordance with the present invention.

### DETAILED DESCRIPTION OF THE INVENTION

An increasingly important consideration in batch processing is the ability to obtain a uniform film thickness across both the surface of individual wafers and across the surfaces of different wafers in a batch of wafers; that is, ideally, not only should a deposited film on a particular wafer be uniform from location to location on one wafer, but the films deposited on different wafers in a single batch of wafers should also be uniform from wafer to wafer. Current practice typically employs low pressures for batch processing, so that efficient gas transport throughout the furnace can be achieved by process gas diffusion, which in turn encourages uniform film deposition over each wafer. Over the vertical height of the process chamber, however, going from the source gas inlet end of the chamber to the exhaust end of the chamber, depletion of process gases can occur. Thus, the concentrations of precursors can decrease with increasing distance from the gas inlet. Where the inlet is at the bottom of a process chamber, the concentrations of process gases decrease along the vertical axis of the furnace, resulting in different deposition rates at different heights in the furnace. Traditionally, this has been addressed by grading the temperature along the axis to compensate for the depletion effect.

In addition to the general difficulties associated with the depletion effect, the deposition of certain films is particularly problematic because the high reactivity of certain precursors used in the deposition exacerbate variations between the various wafers in a batch. Such problematic films include compound films, which comprise at least two elements in a certain ratio. In addition to thickness non-uniformity, differences in the deposition rates of the precursors can cause compositional non-uniformity between films deposited on different wafers.

Examples of such problematic films are silicon germanium alloy films. (see J. Holleman, A. E. T. Kuiper and J. F. Verweij, J. Electrochem. Soc., Vol. 140, No. 6, June 1993, pp.1717-1722). Silicon germanium films are typically deposited using a germanium source gas and a silicon source gas. One factor contributing to non-uniformity problems, however, is that the germanium source gas increases the reactivity of the silicon source gas, which exacerbates the problem of precursor depletion at wafer locations farther from a gas inlet. A second factor is that the reaction rate of the germanium source gas is much higher than the reaction rate of the silicon source gas, causing faster depletion of the germanium source gas. This results in substantial variations in the germanium deposition rate at different locations inside commonly used process chambers, resulting in substantial variations in the germanium content of silicon germanium films deposited on different wafers. The combination of these two factors makes current batch processing methods unsuitable for practical use in forming silicon germanium alloy films.

As noted above, one method to compensate for differences in precursor concentrations has been to apply a temperature gradient over the height of the tube to alter the deposition rate at different points in the reaction chamber. However, this approach introduces new problems as large differences in temperature are undesirable because they can cause differences in the properties of deposited films.

Another currently employed strategy for improving deposited film uniformity on wafers at different positions in the process chamber is the use of a localized source gas injector configured to inject source gas into the process chamber at various locations where wafers are positioned. In this way, the depletion of gas at different positions in the tube is compensated for by the addition of fresh unreacted gas. An example of a furnace with such a localized injector is described in U.S. Pat. No. 5,902,102.

This strategy, however, is not universally applicable since it is best applied to depositing particular types of films using precursors having particular properties. For example, a film that can be deposited using such a localized injector is polycrystalline silicon, deposited using silane (SiH₄). The polycrystalline silicon may later be doped with phosphorus using phosphine (PH₃). For a phosphorus doped film, however, both SiH₄ and PH₃ are typically mixed together prior to feeding the source gases to an injector. This is possible because PH₃ does not react with SiH₄ and even inhibits the decomposition of SiH₄. Another example of a film that can be deposited using such a localized injector is a low temperature oxide, using SiH₄ and O₂ as source gases. In this case, the two source gases are mutually highly reactive and are thus preferably supplied via separate injectors into the furnace tube. However, at the deposition temperatures used for low temperature oxide, 450° C. for example, the individual gases are quite stable and decomposition of the gases inside the injectors is not an issue.

Injectors are not considered suitable for the deposition of silicon germanium alloy films, however, because of the high reactivity of the precursors, especially inside the injector itself. A major perceived obstacle has been that the pressure inside the injector (which in essence are tubes with restrictive apertures) will be so high that uncontrollable reactions may occur inside the injector, leaving little process gas left over for the deposition of films onto the wafer substrates. In addition, as discussed above, large differences in reaction rates between silicon-containing and germanium-containing precursors continue to make it difficult to achieve a uniform film composition over different wafers in a particular batch.

Conceptual Model

Given the limitations of current strategies, while the present teachings are not limited by theory, the benefits of the present invention can be conceptualized and understood by the theoretical model presented below.

The theoretical model describes a reaction system for a binary film. For ease of description, the deposition of silicon germanium alloy films using SiH₄ and GeH₄ will be taken as an example. It will be appreciated, however, that the model is generally applicable to the deposition of other compound films.

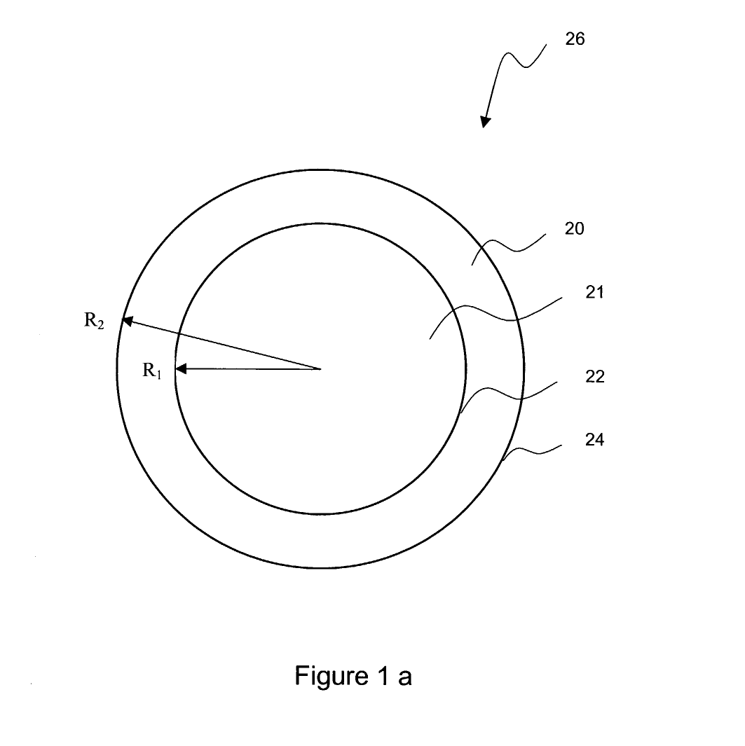

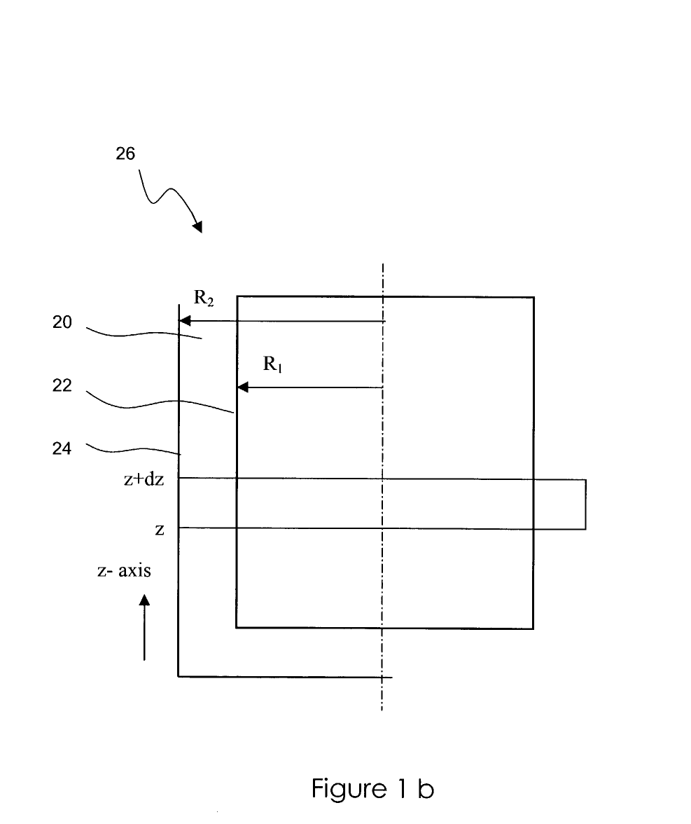

Reference will now be made to the Figures, wherein like numerals refer to like parts throughout. With reference to FIGS. 1a and 1b, a horizontal cross-section of a control volume 20 around wafers 21 that have been loaded into the batch process chamber 26 is assumed to have the shape of a ring. The wafers occupy an area made out by their perimeter 22. The control volume 20 is the space between an internal radius R₁ equal to the radius of perimeter 22 and an external radius R₂ equal to the radius of the inner wall 24 of the process chamber 26 and having a height dz, as shown in FIG. 1b. The wafers are held in a so-called boat (not shown), with individual wafers oriented horizontally and held stacked and spaced apart vertically above and below one another. The boat extends in the z-direction where z increases from the bottom of the process chamber towards the top of the process chamber, up to where the exhaust end of the chamber is located.

The concentration of silane in the control volume 20 at a height z is given by ρ_{SiH4} (z) and the concentration of germane is given by ρ_{GeH4}(z). The amount of silane and germanium that will accumulate in the control volume as a function of time is given by:

$$\begin{matrix}π \cdot ( {R}_{2}^{2} - {R}_{1}^{2} ) \cdot dz \frac{{}_{}^{\partial }{ρ}{}_{{SiH}_{4}}^{} ( z )}{\partial t} = {φ}_{{SiH}_{4}}^{1} + {φ}_{{SiH}_{4}}^{2} + {φ}_{{SiH}_{4}}^{3} + {φ}_{{SiH}_{4}}^{4} & ( 1 ) \\ π \cdot ( {R}_{2}^{2} - {R}_{1}^{2} ) \cdot dz \frac{{}_{}^{\partial }{ρ}{}_{{GeH}_{4}}^{} ( z )}{\partial t} = {φ}_{{GeH}_{4}}^{1} + {φ}_{{GeH}_{4}}^{2} + {φ}_{{GeH}_{4}}^{3} + {φ}_{{GeH}_{4}}^{4} & ( 2 )\end{matrix}$$

wherein the four terms on the right-hand side of each equation are the amount of the gas supplied to and removed from the control volume. Negative values indicate removal from the process chamber, while positive values indicate supply of gases into the process chamber. The expressions on the right hand side are written out below.

$$\begin{matrix}{φ}_{{SiH}_{4}}^{1} = π \cdot ( {R}_{2}^{2} - {R}_{1}^{2} ) \cdot v ( z ) \cdot {ρ}_{{SiH}_{4}} ( z ) & ( 3 ) \\ {φ}_{{SiH}_{4}}^{2} = {v}_{s} \cdot {ρ}_{{SiH}_{4}}^{i} \cdot 2 π \cdot {R}_{2} \cdot dz & ( 4 ) \\ {φ}_{{SiH}_{4}}^{3} = - π \cdot ( {R}_{2}^{2} - {R}_{1}^{2} ) \cdot v ( z + dz ) \cdot {ρ}_{{SiH}_{4}} ( z + dz ) & ( 5 ) \\ {φ}_{{SiH}_{4}}^{4} = - 2 π \cdot {R}_{1}^{2} \cdot ( {K}_{1} \cdot {( {ρ}_{{SiH}_{4}} ( z ) )}^{α1} + {K}_{2} \cdot {( {ρ}_{{SiH}_{4}} ( z ) )}^{α2} \cdot {( {ρ}_{{GeH}_{4}} ( z ) )}^{α3} ) \cdot \frac{dz}{p} & ( 6 )\end{matrix}$$

Equation (3) gives the inflow of silane through the bottom plane of a horizontal cross-section of the control volume 20 at height z and with a velocity ν(z). Equation (4) gives the injection of silane through the outer circumference of the control volume 20, which outer circumference is defined by the inner wall 24. For simplicity, it is assumed that there is a injection of silane over the complete outer circumference of the cylindrical volume 20, with the injected silane having a gas injection velocity νₛ and a density ρⁱ_{SiH4}. Equation (5) gives the outflow of silane through the top plane of a horizontal cross-section of the control volume 20 at height z+dz (FIG. 1b). Equation (6) gives the consumption of the silane by decomposition and deposition of a film on the surfaces of wafers 21, where the total surface area of a wafer (two surfaces) is 2πR₁² and the pitch of a wafer in the boat is p. The constants K₁ and K₂ are rate constants that account for the possible temperature dependence of the decomposition reaction through thermal activation. The parameters α₁, α₂, and α₃ are the reaction order constants for the decomposition reaction.

Below, similar equations are written out for germane, equation (2):

$$\begin{matrix}{φ}_{{GeH}_{4}}^{1} = π \cdot ( {R}_{2}^{2} - {R}_{1}^{2} ) \cdot v ( z ) \cdot {ρ}_{{GeH}_{4}} ( z ) & ( 7 ) \\ {φ}_{{GeH}_{4}}^{2} = {v}_{s} \cdot {ρ}_{{GeH}_{4}}^{i} \cdot 2 π \cdot {R}_{2} \cdot dz & ( 8 )\end{matrix}$$

$$\begin{matrix}{φ}_{{GeH}_{4}}^{3} = - π \cdot ( {R}_{2}^{2} - {R}_{1}^{2} ) \cdot v ( z + dz ) \cdot {ρ}_{{GeH}_{4}} ( z + dz ) & ( 9 ) \\ {φ}_{{GeH}_{4}}^{4} = - 2 π \cdot {R}_{1}^{2} \cdot ( {K}_{3} \cdot {( {ρ}_{{GeH}_{4}} ( z ) )}^{{α}_{4}} + {K}_{4} \cdot {( {ρ}_{{GeH}_{4}} ( z ) )}^{{α}_{5}} \cdot {( {ρ}_{{SiH}_{4}} ( z ) )}^{{α}_{6}} ) \cdot \frac{dz}{p} & ( 10 )\end{matrix}$$

wherein ρⁱ_{GeH4}(z) is the germane density of the injected gas. In equation (10) the constants K₃ and K₄ are rate constants that account for the possible temperature dependence of the decomposition reaction. The parameters α₄, α₅, and α₆ are rate constants for the decomposition reaction. It will be appreciated that both equations (6) and (10) allow for the possibility that the decomposition rate of a species is influenced by a second species.

Preferably, during deposition of a film, a steady state is achieved, so that the rate of precursor entry into the reaction chamber is equal to the rate of precursor deposition. In such a case there is no change of the concentration of the precursor gases as a function of time. As a result, the left hand expressions for both equations (1) and (2) are zero. Therefore, the sum of the equations (3), (4), (5), (6), and the sum of the equations (7), (8), (9), (10) should both be equal to 0.

To verify this result, as a first step in the calculation of the sum of equations (3), (4), (5), and (6), the Taylor expansion of equation (5) can be written out as follows:

$${φ}_{{SiH}_{4}}^{3} = - π \cdot ( {R}_{2}^{2} - {R}_{1}^{2} ) \cdot \\ ( v ( z ) \cdot {ρ}_{{SiH}_{4}} ( z ) + v ( z ) \cdot \frac{d {ρ}_{{SiH}_{4}} ( z )}{dz} \cdot dz + \frac{dv ( z )}{dz} \cdot {ρ}_{{SiH}_{4}} ( z ) \cdot dz + O ( {dz}^{2} ) ) \qquad ( 11 )$$

The first term is opposite to equation (3), and therefore will cancel out when equations (3) and (5) are added. In addition, the term (dZ)² can be ignored due to the coefficient of 0. Therefore, summing (3) and (5) yields:

$${φ}_{{SiH}_{4}}^{1} + {φ}_{{SiH}_{4}}^{3} = - π \cdot ( {R}_{2}^{2} - {R}_{1}^{2} ) \cdot ( v ( z ) \cdot \frac{d {ρ}_{{SiH}_{4}} ( z )}{dz} \cdot dz + \frac{dv ( z )}{dz} \cdot {ρ}_{{SiH}_{4}} ( z ) \cdot dz ) \qquad ( 12 )$$

The value for the gas velocity ν(z) can be calculated from the gas injection velocity νₛ over the injection surface 2πR₂·z:

$$v ( z ) = \frac{2 \cdot π \cdot {R}_{2} \cdot ( {v}_{s} + C ( z ) )}{π \cdot ( {R}_{2}^{2} - {R}_{1}^{2} )} \cdot z \qquad ( 13 )$$

wherein C is a term that depends only on the conversion rate of the precursor gas and takes into account the generation and/or annihilation of gas through chemical reactions, e.g. the thermal decomposition of one SiH₄ molecule can result in the formation of two H₂ molecules.

Notably, when the deposition rate in the reactor is constant over the height of the reactor, which is the theoretical objective of the preferred embodiments then the term C does not depend on z. As such, ν(z) will increase linearly as a function of z. Consequently, in the case where all the precursor gas entering the process chamber is homogeneously distributed, e.g., by using a gas injector as described herein below, ν(z) will be proportional to z.

On the basis of this assumption, the set of differential equations can be written out and solved. After solving the equation, it is possible to argue that the assumption that C is constant is indeed reasonable, as discussed below. Combining equations (13), (12), (11), (4), (6), in equation (1) and simultaneously dividing by 2πdz yields the following:

$$0 = {v}_{s} \cdot {ρ}_{{SiH}_{4}}^{i} \cdot {R}_{2} - \frac{{R}_{1}^{2}}{p} \cdot f ( {ρ}_{{SiH}_{4}} ( z ) , {ρ}_{{GeH}_{4}} ( z ) ) \\ - 2 \cdot π \cdot {R}_{2} \cdot ( {v}_{s} + C ) \cdot ( z \cdot \frac{d {ρ}_{{SiH}_{4}} ( z )}{dz} + {ρ}_{{SiH}_{4}} ( z ) ) \qquad ( 14 )$$

A similar expression can be found for the germane concentration:

$$0 = {v}_{s} \cdot {ρ}_{{GeH}_{4}}^{i} \cdot {R}_{2} - \frac{{R}_{1}^{2}}{p} \cdot g ( {ρ}_{{GeH}_{4}} ( z ) , {ρ}_{{SiH}_{4}} ( z ) ) \\ - 2 \cdot π \cdot {R}_{2} \cdot ( {v}_{s} + C ) \cdot ( z \cdot \frac{d {ρ}_{{GeH}_{4}} ( z )}{dz} + {ρ}_{{GeH}_{4}} ( z ) ) \qquad ( 15 )$$

This set of differential equations has a solution when both ρSiH₄(z) and ρGeH₄(z) are independent of z. In this case, functions f and g are also independent of z and, as a consequence, the following results can be obtained:

$$\begin{matrix}{ρ}_{{SiH}_{4}} ( z ) = \frac{{v}_{s} \cdot {ρ}_{{SiH}_{4}}^{i} \cdot {R}_{2} - \frac{{R}_{1}^{2}}{p} \cdot f ( {ρ}_{{SiH}_{4}} ( z ) , {ρ}_{{GeH}_{4}} ( z ) )}{2 \cdot π \cdot {R}_{2} \cdot ( {v}_{s} + C )} & ( 16 ) \\ {ρ}_{{GeH}_{4}} ( z ) = \frac{{v}_{s} \cdot {ρ}_{{GeH}_{4}}^{i} \cdot {R}_{2} - \frac{{R}_{1}^{2}}{p} \cdot g ( {ρ}_{{GeH}_{4}} ( z ) , {ρ}_{{SiH}_{4}} ( z ) )}{2 \cdot π \cdot {R}_{2} \cdot ( {v}_{s} + C )} & ( 17 )\end{matrix}$$

The solutions exist when the density of the species and the conversion rate of the reactants are constant over the height of the reactor. Notably, the reaction rate equation does not have to fulfill any condition other than the following: if the parameters ρSiH₄(z) and ρGeH₄(z) do not vary as a function of z, then the value of the reaction rate does not vary as a function of z.

As noted above, the outcome of this modeling has general applicability to depositions of compound films other than silicon germanium films. In fact, precursors for other binary films may be readily substituted for the silane and germane discussed above. As such, the model indicates that each binary film can be grown with a constant deposition rate and constant film composition over the height of the process chamber 26, using a separate precursor source gas for each element constituting the binary film, by injecting the two precursor source gases into the reaction chamber 26 in a constant ratio and substantially homogeneously distributed over the height of the reactor. According to the above-described theoretical model, such an injection of precursor gas can result in a homogeneous film over the height of the boat even in cases of substantially different reaction rates for the different source gases.

Process Chamber and Gas Injector

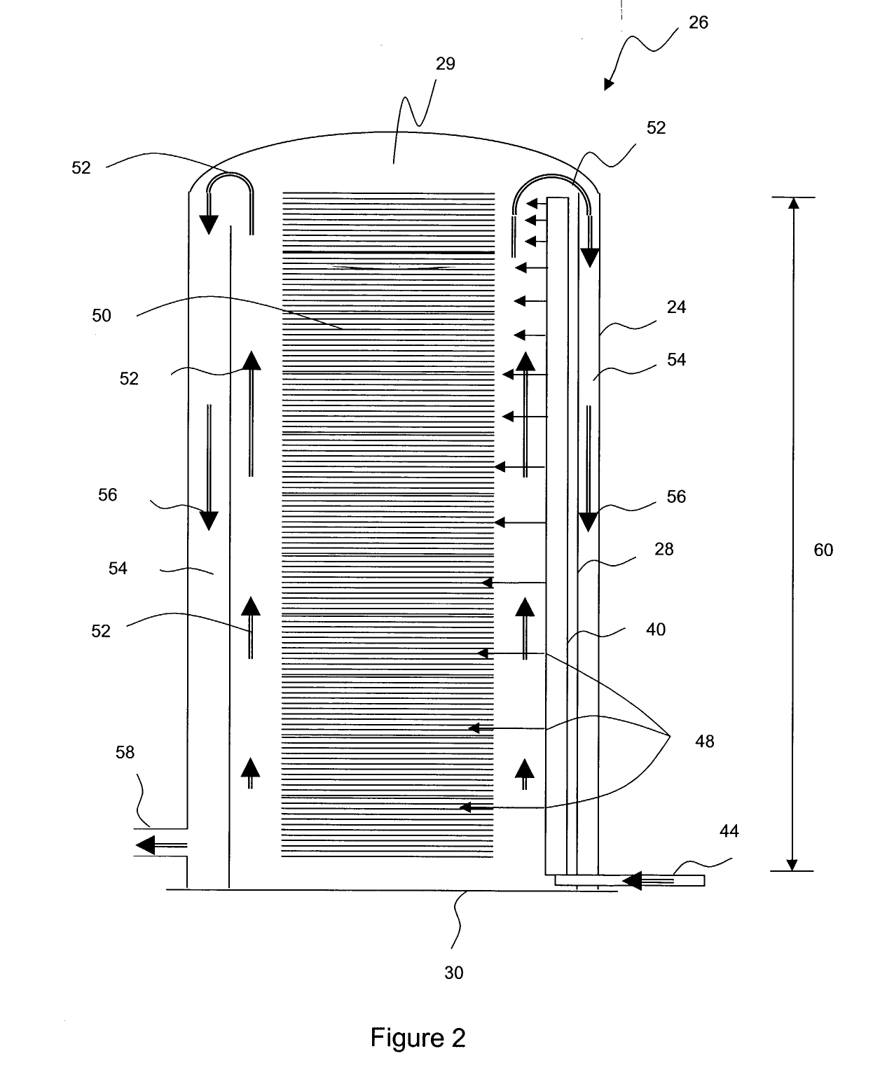

A schematic cross-sectional side-view of an elongated furnace with a gas injector, in accordance with preferred embodiments of the present invention, is shown in FIG. 2. The process chamber 26 is preferably surrounded by a heating element (not shown). A liner 28, delimiting the outer perimeter of the reaction space 29, is preferably provided inside the process chamber 26. Preferably, at the bottom of the process chamber 26, a wafer load 50 may enter and exit the process chamber 26 by a door 30. Precursor source gas is injected through a gas injector 40, preferably via a gas feed conduit 44. The gas injector 40 is provided with a pattern of holes 48, preferably extending substantially over the height of the wafer load 50. Note that, because gases are first introduced into the reaction space 29 from the holes 48 of the gas injector 40, the interior of gas delivery devices, such as the gas injector 40, through which gases travel is not part of the reaction space 29 and is, in a sense, outside of the reaction space 29. Consequently, the reaction space 29 comprises the interior volume of the process chamber 26, excluding the volume occupied by gas delivery devices such as the gas injector 40. Note also that, while illustrated and described in the context of a vertical furnace, the injectors described herein can also be employed with horizontal furnace designs.

In a preferred embodiment, inside the process chamber 26, gas is flowed in a generally upward direction 52 and then removed from the reaction space 29 via the exhaust space 54 between the process chamber 26 and the liner 28, where gas flows in a downward direction 56 to the exhaust 58, which is connected to a pump (not shown). The gas injector 40 preferably distributes process gases inside the process chamber 26 over the entire height of the reaction space 29. The gas injector 40 itself acts as a restriction on the flow of gas, such that the holes 48 that are closer to the conduit 44 tend to inject more gas into the reaction space than those holes 48 that are farther from the conduit 44. Preferably, this tendency for differences in gas flows through the holes 48 can be compensated to an extent by reducing the distance between the holes 48 (i.e., increasing the density of the holes 48) as they are located farther away from the conduit 44. In other embodiments, the size of individual holes making up the holes 48 can increase with increasing distance from the conduit 44, or both the size of the holes 48 can increase and also the distance between the holes 48 can decrease with increasing distance from the conduit 44. Advantageously, however, the preferred embodiments are illustrated with holes 48 of constant size so as to minimize the surface area of the sides of the gas injector 40 containing the holes 48.

In one preferred embodiment, for depositing silicon germanium, the gas injector design advantageously prevents undesired and uncontrollable reactions inside the gas injector. Preferably, as described in more detail below, this is achieved by providing holes 48 in the gas injector 40 such that the total area of the opening of the holes 38 is sufficiently large to allow the pressure inside the gas injector 40 to be kept relatively low, in comparison to the pressures inside the localized injectors described earlier. Reducing the pressure inside the gas injector will result in a reduction of the reaction rate of precursors, since reaction rates typically increase with increasing pressure. An additional advantage of having relatively low pressure inside the gas injector 40 is that gas tends to expand at low pressures, so that the precursor source gases inside the gas injector 40 will expand out and through the gas injector 40. In such a case, for a given constant flow of source gas, the residence times of the source gases inside the gas injector 40 will be reduced relative to another case where similar gases in the injector 40 are at a higher pressure. Because of the combination of these advantages, in particular preferred embodiments, the decomposition of source gases can be substantially eliminated.

A disadvantage, however, of low pressure inside the gas injector 40 is that the conduction of gases through the gas injector 40 is decreased. This can lead to a poor distribution of gas over the height of the gas injector 40, causing differences in the flow of precursor source gas out of the holes 48 over the height of the gas injector 40; that is, the majority of precursor source gas may flow out of the holes 48 near the gas conduit 44 end of the gas injector 40.

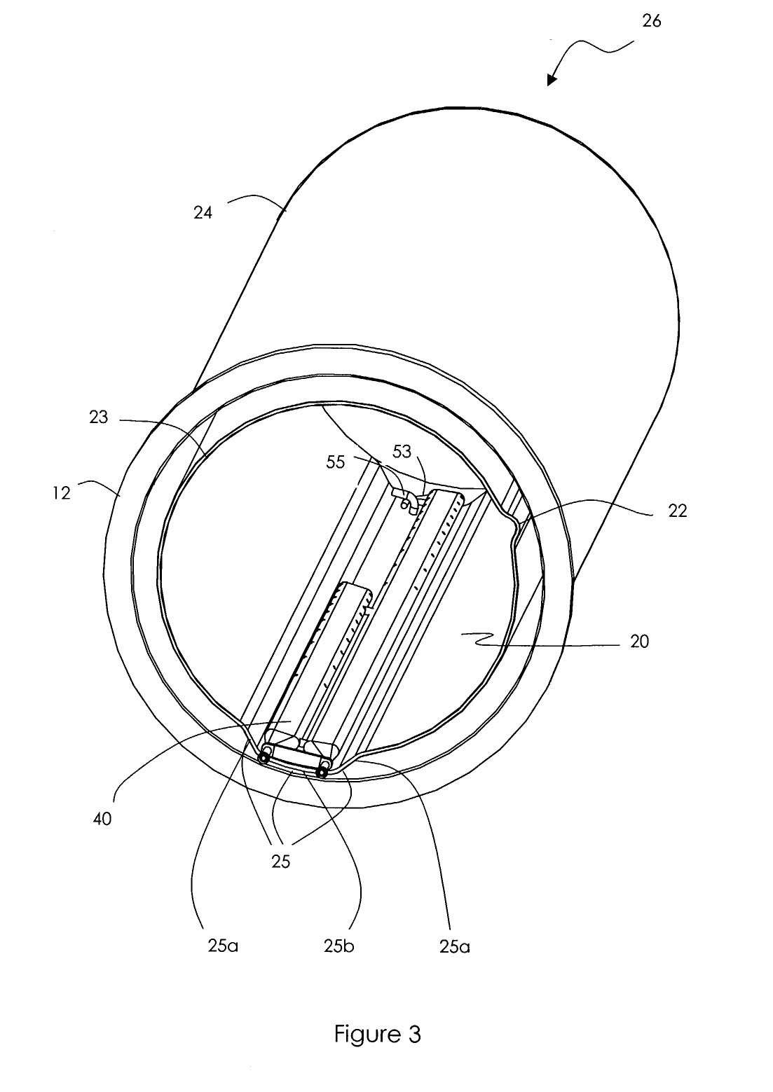

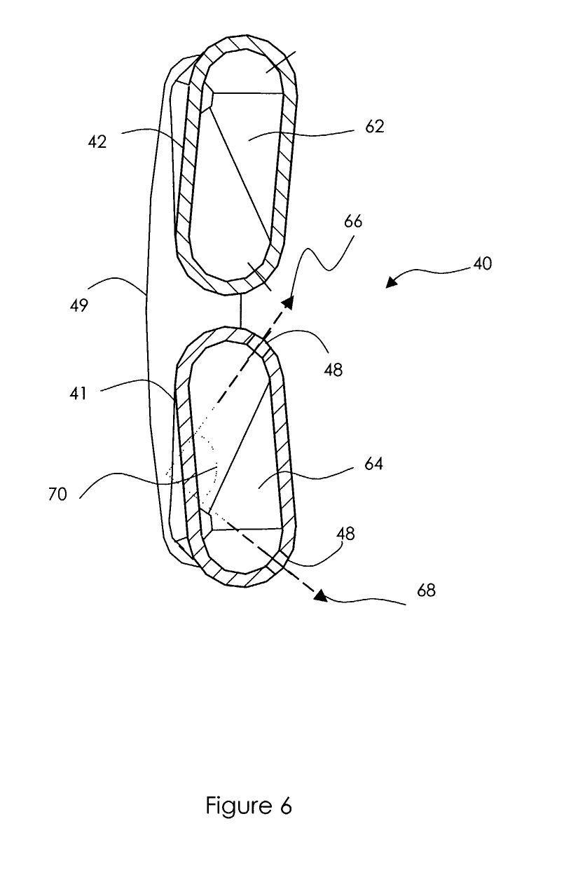

To facilitate the flow of precursor source gas inside and along the height of the gas injector 40, the gas injector 40 is preferably provided with a large inner cross-sectional area. In addition, in one preferred embodiment, in order to better accommodate the preferred gas injector 40 inside the reaction space 29, the wall of the process chamber 26 delimiting the reaction space 29 is provided with an outwardly extending bulge 25 to accommodate the gas injector 40, as shown in FIG. 3. FIG. 3 is a perspective-view of the process chamber 26 of FIG. 2, showing the liner 23 and the gas injector 40 mounted in the liner 23, as viewed from the bottom of the process chamber 26. The gas injector 40 is accommodated in the bulge 25 in the liner 23. A second bulge 22 is also preferably provided in the liner 23 to accommodate a thermocouple (not shown) for measurement of the temperature inside the reaction space 29. By accommodating the gas injector 40 and the thermocouple in the bulge 25 and second bulge 22, respectively, that extend outwardly into the space between the liner 23 and inner wall 24, the reaction space 29 can be kept substantially cylindrical. Thus, the side of the gas injector 40 facing the center of the reaction space 29 is preferably substantially flush with an imaginary circular circumference of the reaction space 29. Such a substantially cylindrical reaction space 29 is advantageous for the uniformity of the gas flow and the film deposition process. In addition, as illustrated in FIG. 3, the sides 25a of the bulge 25 preferably slope gradually to meet the side 25b of the bulge 25, allowing space at the sides to the gas injector 40 for precursor gas to be emitted in the directions 65 and 68 (FIG. 6).

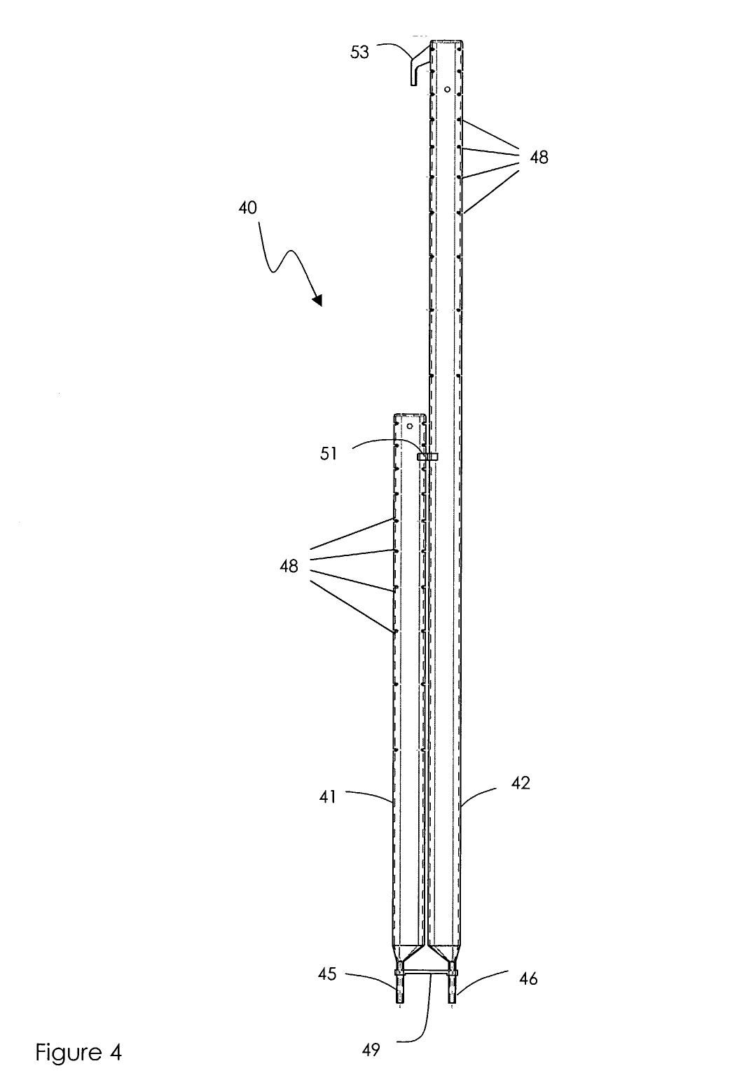

The gas injector 40 in accordance with one illustrative embodiment of the present invention is shown in FIG. 4. The gas injector 40 preferably comprises two gas injector parts 41, and 42, each preferably provided with separate gas feed conduit connections 45 and 46, respectively. Part 41 injects gas into the lower volume of the reaction space 29 and part 42 injects gas into the upper volume of the reaction space 29. The parts 41 and 42 are connected by linkages 49 and 51. It will be appreciated, however, that the gas injector 40 may comprise more or fewer parts than the two parts 41 and 42.

The gas injector 40 is provided with a pattern of holes 48 substantially extending over the height 60 (FIG. 2) of the wafer load 50 (FIG. 2). The total cross section of the holes is preferably at least about 30 mm². The diameter of each of holes 48 is preferably about 1 mm or more, more preferably between about 2.5 mm and 3.5 mm, and most preferably about 3 mm. In the illustrative embodiment shown in FIG. 4, the gas injector 40 has 40 holes total. Consequently, with an average diameter of 3 mm per hole, the total cross-sectional area of the holes 48 is 40×3 mm×3 mm×π/4=282 mm². More generally, the total cross-sectional area of the holes 48 is preferably about 30 mm² or more, and more preferably between about 196 mm² and 385 mm².

In addition, each part 41 and 42 of the gas injector 40 has an inner cross-sectional area 64 and 62 (FIG. 6), respectively, which are the cross-sectional areas in each of parts 41 and 42 available for the conduction of source gases through the gas injector 40. Preferably, each of inner cross-sectional areas 64 and 62 are at least about 100 mm². In the illustrative embodiment, the cross-sectional area of each of the parts 41, 42 of the gas injector 40 can be about 11 mm×30 mm=330 mm². More generally, the cross-sectional area of each of the parts 41, 42 is between about 140 mm² and 600 mm², more preferably between about 225 mm² and 455 mm², and most preferably between about 290 mm² and 372 mm². At its top end, the gas injector 40 can be provided with a hook 53 (FIGS. 3, 4 and 5), to secure the top end of the gas injector 40 to the hook support 53 (FIG. 3). It will be appreciated that the gas injector 40 may be secured by other means suitable for mounting it inside the process chamber 26.

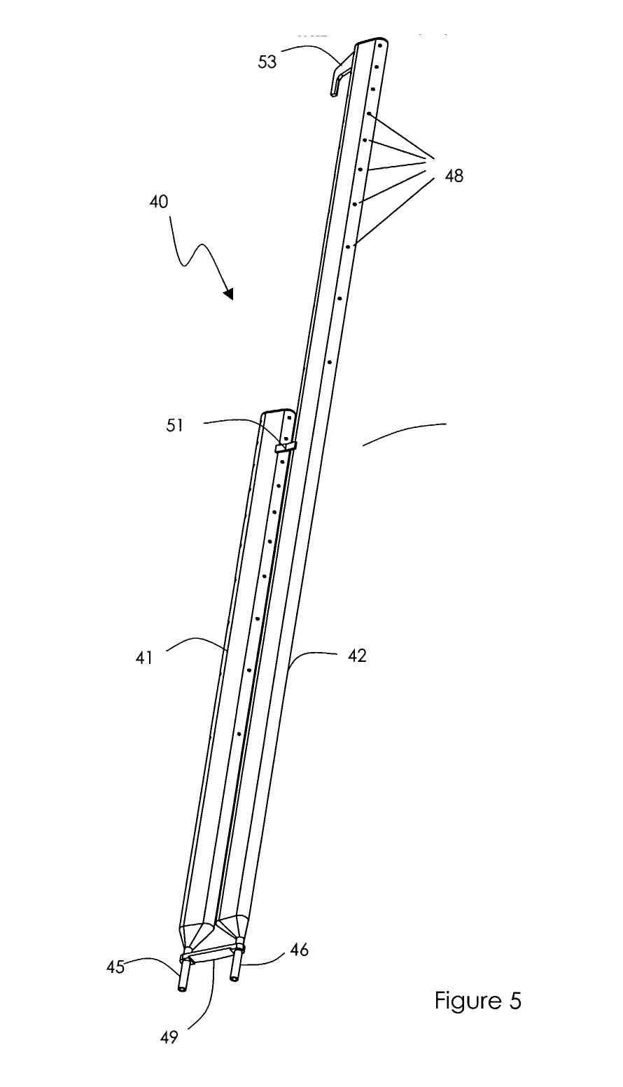

Reference will now be made to FIGS. 4-7, identical parts are indicated with identical reference numerals throughout. A perspective view of the gas injector 40 is presented in FIG. 5. A horizontal cross-section of the gas injector 40 is shown in FIG. 6. The cross-section is taken through the lower end of the gas injector 40 and straight through a pair of injection holes 48 provided in gas injector part 41, for injecting the gas in the lower end of the process chamber 26. Preferably, in each gas injector part, the holes 48 are provided in pairs, at the same height. In addition, the two holes 48 preferably inject the precursor gas in two directions 66 and 68, the directions 66 and 68 forming an angle 70 of about 90 degrees, to improve the radial uniformity. Moreover, as shown, the tubes comprising the gas injector 40 preferably have an oblong shape, as viewed in horizontal cross-section. Preferably, the longer dimension of the oblong shape faces the center of the process chamber 26, i.e., the side of the oblong shape with the longer dimension is perpendicular to a imaginary line extending radially from the center of the process chamber 26.

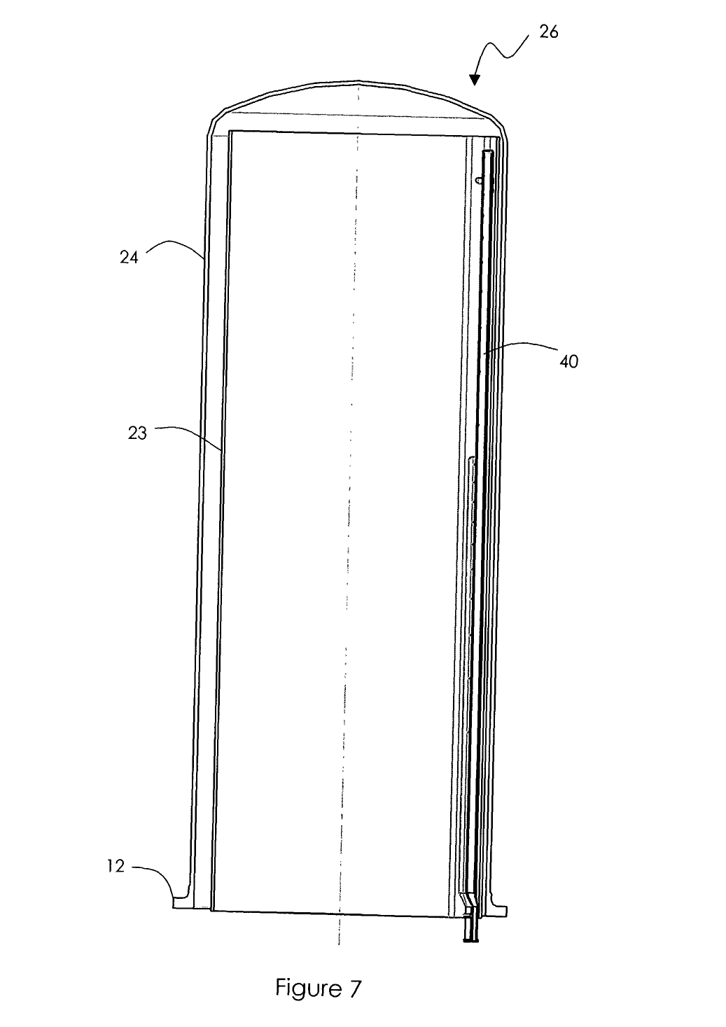

FIG. 7 shows the placement of the gas injector 40 in the process chamber 26, according to preferred embodiments of the present invention. The process chamber 26 is preferably provided at its bottom end with a flange 12. The liner 23 is preferably placed inside the process chamber 26. Preferably, the gas injector 40 is placed inside the liner 23.

In a preferred embodiment, two precursor source gases, providing the two constituting elements of a binary film, are mixed in the gas supply system (not shown) prior to entering the gas injector 40 via feed conduit connections 45 and 46 (FIGS. 4 and 5). Pre-mixing the precursor gases in the gas supply system is one way to ensure a homogeneous composition of injected gas over the height of the boat. However, pre-mixing is not essential. In another embodiment, the two precursor source gases can each be injected via their own separate gas injectors 40 (not shown), so that they are first mixed after being injected into the reaction space 29. Consequently, it will be appreciated that more than one gas injector 40 may be located inside the process chamber 26.

Advantageously, the use of two gas injector parts 41 and 42 allows for further tuning possibilities. For example, when a gas of substantially the same composition is supplied to both parts of the gas injector 40, via separate source gas supplies and gas feed conduit connections 45 and 46, the flows supplied to the different gas injector parts can be chosen differently to fine-tune the gas flow into the reaction space 29. This will improve uniformity in the deposition rates of precursors over the height 60 of the wafer load 50 (FIG. 2). It is also possible to supply gases of different compositions to the two parts 41 and 42 of the gas injector 40 to fine-tune, over the height 60 of the wafer load 50, the composition of a deposited binary film. However, as indicated by the theoretical model discussed above, the compositions of the injected precursor source gases fed into gas injector parts 41 and 42 are more preferably the same for both parts.

### EXAMPLES

Depositions of silicon germanium films were carried out and the results were analyzed. In a first experiment the deposition was carried out without a gas injector 40, by a system according to the prior art. Silane and germane were fed to a vertically elongated process chamber. The process chamber was configured to accommodate a load of wafers with a diameter up to 200 mm. The diameter of the wafers actually used, however, was 150 mm. All the precursor source gases were injected from one point, at the bottom end of the reaction space. The silane flow was 200 sccm, the germane flow was 15 sccm, the temperature was 460° C., the pressure was 1000 mTorr, and the deposition time was 92 minutes.

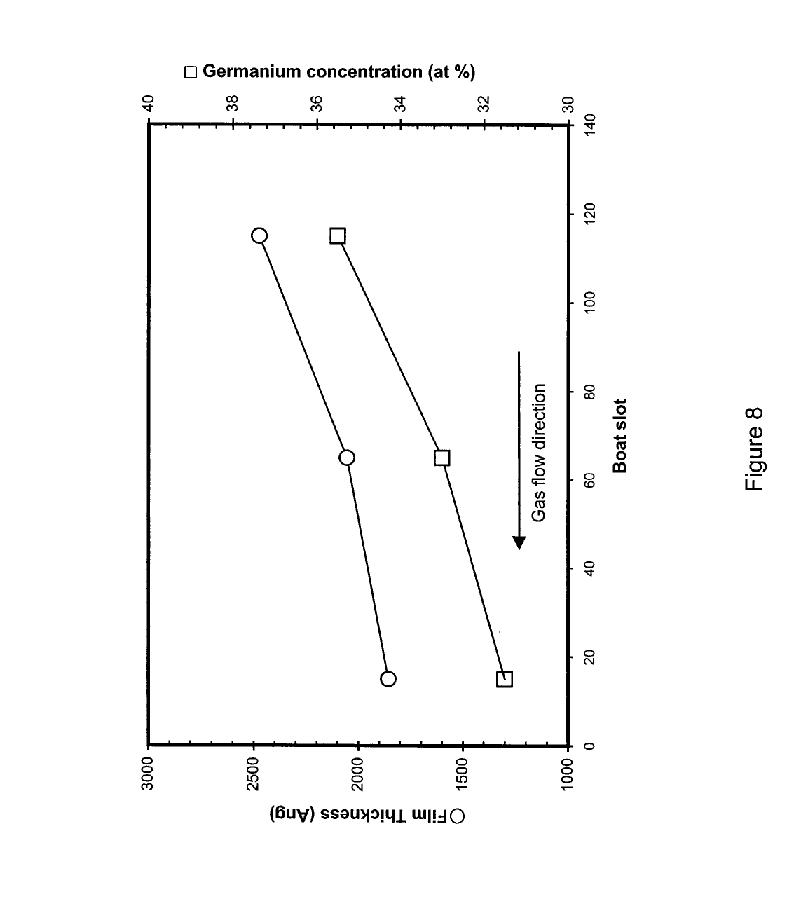

The results in terms of film thickness and composition were determined and are presented in FIG. 8. The horizontal axis indicates the location of the wafers in the boat. Boat slot 1 was at the top of the boat and boat slot 140 was at the bottom of the boat. The general direction of the gas flow is as indicated in FIG. 8. A pronounced variation in both film thickness and film composition can be observed, due to depletion of source gas, particularly depletion of germane. The variation in film thickness (indicated by the plot with circles), calculated by taking the difference between the maximum and minimum film thicknesses and dividing by two times the average [(Max−Min)/(2×AVG)], is about +/−15%. For the germanium concentration (indicated by the plot with squares) the variation was about +/−6%.

In a second experiment the deposition was carried out using the methods and apparatus of the preferred embodiment. Silane and germane were pre-mixed and injected into the reaction space together via a gas injector 40 (FIG. 4), as described above. The silane flow was 480 sccm, the germane flow was 60 sccm, the temperature was 490° C., the pressure was 200 mTorr and the deposition time was 60 minutes.

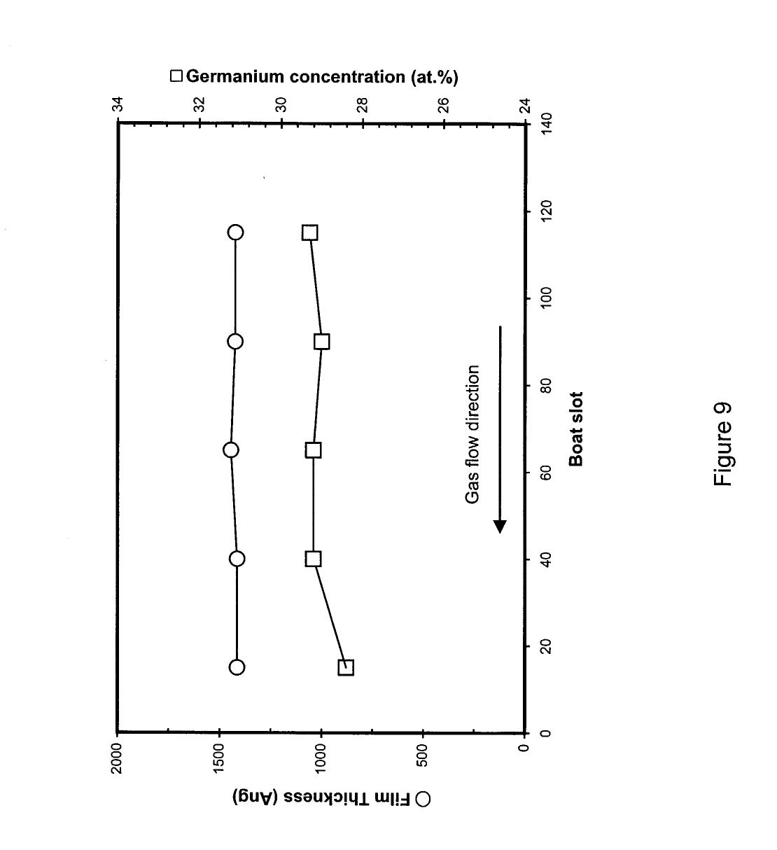

The results are shown in FIG. 9. Relative to the results of the prior art process shown in FIG. 8, a much more uniform film thickness profile and germanium concentration over the boat was achieved. In this case, the variation in film thicknesses thickness (indicated by the plot with circles) is only about ±1.1% and the variation in germanium concentration (indicated by the plot with squares) is about ±1.5%.

Advantageously, in addition to improved uniformity in thickness and composition, another advantage was achieved. It has been observed that the growth of polycrystalline silicon germanium layers on silicon oxide is difficult because nucleation of the film on the oxide layer is very difficult and this difficulty prevents deposition of the film in a large process window. This problem has been overcome by depositing a seeding layer, typically of pure silicon, on top of the silicon oxide before deposition of the silicon germanium layer. However, using the apparatus and methods of the present invention, the problems with nucleation were substantially eliminated and smooth silicon germanium films were deposited directly on silicon oxide, using a mixture of source gases wherein the ratio of germanium atoms to germanium plus silicon atoms is 1 to 20 or higher. Desirably, omitting the seeding layer simplifies the fabrication of integrated circuits.

Although, for ease of discussion, silane (SiH₄) and germane (GeH₄) have been identified as precursor source gases, the use of other precursor source gases is also contemplated. For example, other silicon sources include, but are not limited to, mono-, di-, tri- or tetrachlorosilane (SiH₍₁₋ₓ₎Clₓ, x=1-4), or disilane (Si₂H₆) or trisilane (Si₃H₈). Similarly, other germanium sources can include, but are not limited to, mono-, di-, tri- or tetrachlorogermane (GeH₍₁₋ₓ₎Clₓ, x=1-4), digermane (Ge₂H₆) or trigermane (Ge₃H₈). It will be appreciated that, using these other source gases, process conditions should be optimized. Moreover, the precursor source gases need not be strictly composed of two precursor sources. It is possible to add dopants to the silicon germanium film. For example, boron can be added through the addition of a boron-containing source gas such as diborane (B₂H₆) or boron chloride (BCl₃).

Moreover, it will be appreciated that the present invention has applicability to depositing compound films other than silicon germanium films. In particular, the present invention may advantageously be applied to the deposition of other compound layers having precursors with highly reactive chemistries, especially precursors that cannot be used in conjunction with the localized injectors of the prior art. An example of other compound films includes arsenic doped films, using TEOS (Si(—OC₂H₅)₄) and TEAS (AsO(—OC₂H₅)₃) as precursor source gases. The present teachings may also be applied to the deposition of undoped silicon oxide films, using TEOS (Si(—OC₂H₅)₄) as a source gas. Strong height-dependent variations in deposition rate can still occur with this process. In such a case, a boat with a variable pitch, according to U.S. Pat. No. 6,240,875 B1, owned by the assignee of the present application, may be used. In conjunction with the variable pitch boat, injecting TEOS through a gas injector as described in the present disclosure appeared to result in excellent deposited film uniformities. The present invention may also be applied to the deposition of high temperature oxides using silane and N₂O or dichlorosilane (DCS) and N₂O. In addition, deposition of silicon nitride films using dichlorosilane (DCS) and ammonia or using bis-(tertiary-butyl amino) silane and ammonia can favorably be carried out in accordance with the preferred embodiments. It will be appreciated, however, that the foregoing examples are illustrative only and not exhaustive.

Consequently, although this invention has been described on the basis of particular preferred embodiments, modifications of the invention are possible and are within the spirit and scope of this disclosure. This disclosure is intended to cover modifications, adaptations or variations of the invention which make use of its general principles. Furthermore, the invention was described in the context of semiconductor manufacturing processes, but those of skill in the art will recognize that it may be adapted for use in various industries. For example, adaptation and use in applications such as chemical production is possible.

We claim:

1. A chemical vapor deposition furnace for depositing silicon germanium films on a plurality of wafers, comprising:
a process chamber, wherein the process chamber is elongated in a generally vertical direction;
a boat to support the plurality of wafers, wherein individual wafers comprising the plurality of wafers are oriented substantially horizontally, stacked and spaced apart vertically; and
a gas injector inside the process chamber, wherein the gas injector extends in a generally vertical direction over about a boat height and comprises a plurality of vertically spaced gas injection holes and wherein the gas injector has a feed end connected to a source of a silicon-containing gas and a source of a germanium-containing gas.

2. The chemical vapor deposition furnace of claim 1, wherein a horizontal cross-section of a channel inside the gas injector for conducting gas has an oblong shape, wherein a side of the oblong shape having a longer dimension faces toward a center of the process chamber.

3. The chemical vapor deposition furnace of claim 2, wherein an interior surface delimiting a reaction space inside the process chamber has an outwardly extending bulge that accommodates the gas injector.

4. The chemical vapor deposition furnace of claim 3, wherein the side of the oblong shape is roughly flush with a substantially circular circumference of the reaction space.

5. The chemical vapor deposition furnace of claim 1, wherein the plurality of gas injection holes extends over about a height of the gas injector.

6. The chemical vapor deposition furnace of claim 5, wherein the gas injector comprises two or more injector tubes, each injector tube being connected to a separate gas supply conduit for feeding gas into the injector tube.

7. The chemical vapor deposition furnace of claim 6, wherein the gas injection holes of an injector tube extend over less than a vertical length of the injector tube.

8. The chemical vapor deposition furnace of claim 6, wherein each separate gas supply conduit is connected to a different gas source.

9. The chemical vapor deposition furnace of claim 8, wherein the silicon-containing gas and the germanium-containing gas are kept separate until exiting the gas injector.

10. The chemical vapor deposition furnace of claim 1, wherein the gas injection holes each have a gas injection hole diameter of at least about 1 mm.

11. The chemical vapor deposition furnace of claim 10, wherein all gas injection hole diameters are substantially equal.

12. The chemical vapor deposition furnace of claim 11, wherein the diameter of the gas injection holes is about 3 mm.

13. The chemical vapor deposition furnace of claim 1, wherein each gas injection hole has a gas injection hole area, wherein an aggregate area of all the gas injection hole areas is at least about 30 mm2.

14. The chemical vapor deposition furnace of claim 13, wherein the aggregate area of all the gas injection hole areas is between about 196 mm² and 385 mm².

15. The chemical vapor deposition furnace of claim 14, wherein a horizontal cross-sectional area of a channel inside the gas injector for conducting gas is between about 140 mm² and 600 mm².

16. The chemical vapor deposition furnace of claim 14, wherein the horizontal cross-sectional area is between about 225 mm² and 455 mm².

17. The chemical vapor deposition furnace of claim 1, wherein a vertical hole separation distance between neighboring gas injection holes decreases as a feed end distance between the gas injection holes and the feed end of the gas injector increases.

18. The chemical vapor deposition furnace of claim 17, wherein the gas injection holes on the injector are spaced apart vertically and horizontally.

19. The chemical vapor deposition furnace of claim 18, wherein the gas injection holes are configured to inject gas into the process chamber in at least two different horizontal directions.

20. The chemical vapor deposition furnace of claim 19, wherein a first set of gas injection holes form a first vertical line and a second set of gas injection holes form a second vertical line, the first vertical line and the second vertical line being spaced apart horizontally.

21. The chemical vapor deposition furnace of claim 1, wherein the silicon-containing gas and the germanium-containing gas are mixed prior to being fed into the gas injector.

22. The chemical vapor deposition furnace of claim 1, wherein the silicon-containing gas comprises silane.

23. The chemical vapor deposition furnace of claim 1, wherein the silicon-containing gas comprises one or more compounds chosen from a group consisting of monochlorosilane, dichlorosilane, trichlorosilane, tetrachlorosilane, disilane and trisilane.

24. The chemical vapor deposition furnace of claim 1, wherein the germanium-containing gas comprises germane.

25. The chemical vapor deposition furnace of claim 1, wherein the germanium-containing gas comprises one or more compounds chosen from a group consisting of monochlorogermane, dichlorogermane, trichlorogermane, tetrachlorogermane, digermane, and trigermane.

26. The chemical vapor deposition furnace of claim 1, wherein the gas injector is connected to a source of a boron-containing gas.

27. The chemical vapor deposition furnace of claim 26, wherein the boron-containing gas is diborane or borontrichloride.

28. A gas injector for releasing gases into a chemical vapor deposition chamber, the gas injector comprising:
an elongated and hollow structure located inside the chamber, wherein the structure has a plurality of holes along a length of the structure and wherein the structure is accommodated in an outwardly extending bulge of an interior surface delimiting a reaction space inside the chamber; and
a feed end at a bottom of the structure, wherein the feed end is connected to a source of a first precursor gas and a source of a second precursor gas and wherein an aggregate area of gas injection holes per unit length of the structure increases with increasing distance from the feed end.

29. The gas injector of claim 28, wherein the chamber extends in a vertical direction.

30. The gas injector of claim 29, wherein the gas injector extends in the vertical direction.

31. The gas injector of claim 28, wherein a total area of all the gas injection hole areas is at least 30 mm².

32. The gas injector of claim 31, wherein a total area of all the gas injection hole areas is between about 196 mm² and 385 mm².

33. The gas injector of claim 31, wherein a hollow horizontal cross-sectional area of the structure is between about 140 mm² and 600 mm².

34. The gas injector of claim 33, wherein a hollow horizontal cross-sectional area of the structure is between about 225 mm² and 455 mm².

35. The gas injector of claim 28, wherein a hole diameter increases with increasing distance from the feed end.

36. The gas injector of claim 35, wherein a vertical separation distance between holes decreases with increasing distance from the feed end.

37. The gas injector of claim 28, wherein all hole diameters are substantially equal and wherein a vertical separation distance between holes decreases with increasing distance from the feed end.

38. The gas injector of claim 28, wherein a shape of a horizontal cross-section of the hollow structure is oval.

39. The gas injector of claim 38, wherein a side of the gas injector facing a center of the reaction space is roughly flush with a substantially circular circumference of the reaction space.

40. The gas injector of claim 28, wherein the gas injector comprises a first and a second vertically extending, elongated and hollow structures.

41. The gas injector of claim 40, wherein the first and the second structures are fastened together.

42. The gas injector of claim 41, wherein the first structure is longer than the second structure.

43. The gas injector of claim 42, wherein a first plurality of holes extends along about an entire length of the second structure and a second plurality of holes extends along the first structure from about a top of the second structure to about a top of the first structure.

44. The gas injector of claim 28, wherein the first precursor gas is a silicon-containing gas.

45. The gas injector of claim 44, wherein the second precursor gas is a germanium-containing gas.

46. The gas injector of claim 44, wherein the silicon-containing gas comprises silane and the germanium-containing gas comprises germane.

47. The gas injector of claim 44, wherein the silicon-containing gas comprises TEOS and the second precursor gas comprises TEAS.

48. The gas injector of claim 44, wherein the silicon containing gas comprises silane and the second precursor gas comprises N₂O.

49. The gas injector of claim 44, wherein the silicon containing gas comprises dichlorosilane and the second precursor gas comprises N₂O.

50. The gas injector of claim 44, wherein the silicon containing gas comprises dichlorosilane and the second precursor gas comprises NH₃.

51. The gas injector of claim 44, wherein the silicon containing gas comprises bis-(tertiary-butyl amino) silane and the second precursor gas comprises NH₃.

52. A method for manufacturing semiconductor devices, comprising:
flowing a reactant gas up a vertical axis of a chemical vapor deposition chamber to a plurality of locations along the axis; and
horizontally distributing the reactant gas from the plurality of locations into a reaction space in the chamber, wherein flowing the reactant gas is performed inside the chamber and outside the reaction space and wherein the reactant gas comprises a silicon-containing gas and a germanium-containing gas.

53. The method of claim 52, wherein the silicon-containing gas and the germanium-containing gas are kept separate until distributing.

54. The method of claim 52, wherein the silicon-containing gas comprises one or more compounds chosen from a group consisting of monochlorosilane, dichlorosilane, trichlorosilane, tetrachlorosilane, silane, disilane, and trisilane.

55. The method of claim 52, wherein the germanium-containing gas comprises one or more compounds chosen from a group consisting of monochlorogermane, dichlorogermane, trichlorogermane, tetrachlorogermane, germane, digermane, and trigermane.

56. The method of claim 52, wherein horizontally distributing the reactant gas comprises introducing the reactant gas into the reaction chamber in two different horizontal directions.

57. The method of claim 52, wherein the two different horizontal directions form an angle of about 90 degrees.

58. The method of claim 52, wherein the plurality of locations comprises a plurality of holes.

59. The method of claim 58, wherein an aggregate area of the plurality of holes is between about 196 mm² and 385 mm².

60. The method of claim 59, wherein flowing comprises conducting the reactant gas through a structure having a horizontal cross-sectional area between about 225 mm² and 455 mm².

61. The method of claim 52, wherein the reactant gas comprises a dopant-containing gas.

62. The method of claim 61, wherein the dopant-containing gas comprises a boron containing gas.

63. The method of claim 62, wherein the boron-containing gas comprises B₂H₆.

64. The method of claim 62, wherein the dopant-containing gas comprises BCl₃.

65. The method of claim 52, further comprising inserting a boat into the chamber, wherein the boat is capable of supporting a plurality of wafers, wherein individual wafers comprising the plurality of wafers are oriented substantially horizontally, stacked and spaced apart vertically.

66. The method of claim 65, wherein at least part of a surface of the wafers comprises a silicon oxide film and wherein the film is exposed to the reactant gas, wherein a ratio of germanium atoms to germanium plus silicon atoms in the reactant gas is at least about 1 to 20.

67. The method of claim 52, wherein the reactant gas comprises a first gas mixture and further comprising:
flowing a second gas mixture up a second vertical axis of the chamber to a second plurality of locations along the second axis; and
horizontally distributing the second gas mixture from the second plurality of locations into the reaction space, wherein flowing the second gas mixture is performed inside the chamber and outside the reaction space.

68. The method of claim 67, wherein the first gas mixture and the second gas mixture comprise silicon-containing and germanium-containing gases.

69. The method of claim 68, wherein the first gas mixture and the second gas mixture have substantially similar compositions.

70. The method of claim 68, wherein a first rate of flow for horizontally flowing the first gas mixture is substantially equal to a second rate of flow for horizontally flowing the second gas mixture.
